(19) United States
(12) Patent Application Publication
(10) Pub. No.: US 2016/0284572 A1
(43) Pub. Date: Sep. 29, 2016

(54) HEATER BLOCK AND SUBSTRATE PROCESSING APPARATUS

(71) Applicant: AP SYSTEMS INC., Hwaseong-Si (KR)

(72) Inventors: Pil Seong JEONG, Yongin-Si (KR); Sang Hyun JI, Yongin-Si (KR); Sung Yong LEE, Yongin-Si (KR); Yong Woo HAN, Osan-Si (KR)

(21) Appl. No.: 15/051,660

(22) Filed: Feb. 23, 2016

(30) Foreign Application Priority Data
Mar. 27, 2015 (KR) 10-2015-0042995

(51) Int. Cl. H01L 21/67; H05B 1/02

(52) U.S. Cl. CPC H01L 21/67115; H05B 1/0233

(57) ABSTRACT

Present disclosure relates to a heater block including a plurality of heating lamps mounted on one surface thereof facing an object to be processed, e.g., a substrate and a substrate processing apparatus including the same. The heating lamp includes a first lamp configured to irradiate ultraviolet (UV) rays to the object to be processed and a second lamp configured to irradiate infrared (IR) rays to the object to be processed. A relative ratio of the number of first lamp to the number of second lamp is different for each of a plurality of areas on the one surface. Provided are the heater block that may thermally compensate a temperature of an edge area of the substrate to increase temperature uniformity of the substrate and the substrate processing apparatus.

### CROSS-REFERENCE TO RELATED APPLICATION

This application claims priority to Korean Patent Application No. 10-2015-0042995 filed on Mar. 27, 2015 and all the benefits accruing therefrom under 35 U.S.C. §119, the contents of which are incorporated by reference in their entirety.

### BACKGROUND

The present disclosure relates to a substrate processing apparatus, and more particularly, to a heater block of which a structure is improved to increase temperature uniformity of a substrate and a substrate processing apparatus including the same.

A semiconductor and a display apparatus are manufactured in a method in which a unit process such as thin film lamination, ion implantation, and heat treatment is repeatedly performed on a substrate to form a device having desirable circuit operation characteristics on the substrate.

An apparatus used for the process for heat-treating substrate of the unit processes includes a rapid heat treatment apparatus. The rapid heat treatment apparatus transfer heat to the substrate by using ultraviolet rays and infrared rays. For this, the rapid thermal treatment apparatus includes an infrared rays lamp and an ultraviolet rays lamp as disclosed in, e.g., Korean Patent Laid-Open Application No. 10-2002-0085452.

Meanwhile, when the rapid heat treatment apparatus processes the substrate, a quality of the substrate is affected by temperature uniformity of the substrate. Accordingly, it is desirable that each of the infrared rays lamp and the ultraviolet rays lamp has a structure that increases the temperature uniformity of the substrate.

However, in the related art, as disclosed in Korean Patent Laid-Open Application, the linear lamp type infrared rays lamp and ultraviolet rays lamp are provided. Thus, in the related art, since thermal compensation of the substrate to be processed is performed by a one-dimensional compensation method, there are limitations to increase the temperature uniformity for an entire area of the substrate and compensate a temperature of an edge of the substrate.

Also, in the related art, as disclosed in the Korean Patent Laid-Open Application, the infrared rays lamp and the ultraviolet rays lamp are alternately provided in a lattice structure. Thus, in the related art, the infrared rays lamp and the ultraviolet rays lamp are interfered with each other to reduce light radiant energy generated from the infrared rays lamp and decrease a lifetime of the ultraviolet rays lamp due to the infrared rays radiant energy.

### RELATED ART DOCUMENTS

### Patent Documents

(Patent Document 1) KR10-2002-0085452 A

### SUMMARY

The present disclosure provides a heater block of which a structure is improved to increase efficiency of heat-treatment of a substrate and a substrate processing apparatus.

The present disclosure also provides a heater block of which a structure is improved to increase temperature uniformity of a substrate and a substrate processing apparatus.

The present disclosure also provides a heater block of which a structure is improved to suppress or prevent thermal interference and an energy reduction phenomenon between lamps different from each other and a substrate processing apparatus.

The present disclosure also provides a heater block of which a structure is improved to increase a lifetime of a lamp irradiating ultraviolet rays and a substrate processing apparatus.

In accordance with an exemplary embodiment, a heater block includes a plurality of heating lamps mounted on one surface thereof facing an object to be processed.

The heating lamp includes a first lamp configured to irradiate ultraviolet (UV) rays to the object to be processed and a second lamp configured to irradiate infrared (IR) rays to the object to be processed. A relative ratio of the number of first lamp to the number of second lamp is different for each of a plurality of areas on the one surface.

The plurality of areas on the one surface may include a central area having a size and shape corresponding to those of the object to be processed and a surrounding area surrounding the central area.

The first lamp and the second lamp may be mounted together on each of the central area and the surrounding area.

The first lamp and the second lamp may be mounted together on the central area, and the second lamp may be mounted on the surrounding area.

The first lamp may be mounted on the central area, and the first lamp and the second lamp may be mounted together on the surrounding area.

The first lamp may be mounted on the central area, and the second lamp may be mounted on the surrounding area.

The number of first lamp mounted on the central area may exceed approximately 50% of the total number of heating lamp mounted on the central area.

The number of second lamp mounted on the surrounding area may exceed approximately 50% of the total number of heating lamp mounted on the surrounding area.

The first lamp and the second lamp may be selectively mounted on a boundary between the central area and the surrounding area. The first lamp may be mounted when a surface area of the heating lamp on the central area is equal to or greater than approximately 50% of an entire surface area of the heating lamp with reference to the boundary between the central area and the surrounding area, and the second lamp may be mounted when the surface area of the heating lamp on the surrounding area exceeds approximately 50% of the entire surface area of the heating lamp with reference to the boundary between the central area and the surrounding area.

In accordance with another exemplary embodiment, a substrate processing apparatus configured to process a substrate, the substrate processing apparatus includes: a chamber having an inner space in which the substrate is processed; a substrate support unit disposed in the chamber to support the substrate; a heater block disposed to face the substrate support unit; and a transmission member disposed between the chamber and the heater block. A first lamp configured to irradiate ultraviolet (UV) rays to the substrate and a second lamp configured to irradiate infrared (IR) rays to the substrate are provided in plurality and spaced apart from each other on one surface of the heater block facing the substrate.

The one surface of the heater block may include a central area facing an object to be processed and a surrounding area surrounding the central area, and the first lamp may be mounted on at least the central area of the central area and the surrounding area of the one surface.

The one surface of the heater block may include a central area facing the object to be processed and a surrounding area surrounding the central area, and the second lamp may be mounted on at least the surrounding area of the central area and the surrounding area of the one surface.

A ratio of the number of first lamp to the number of second lamp may be different for each of the central area and the surrounding area.

The number of first lamp mounted on the central area may exceed approximately 50% of the total number of heating lamp mounted on the central area, and the number of second lamp mounted on the surrounding area may exceed approximately 50% of the total number of heating lamp mounted on the surrounding area.

### BRIEF DESCRIPTION OF THE DRAWINGS

Exemplary embodiments can be understood in more detail from the following description taken in conjunction with the accompanying drawings, in which:

FIG. 1 is a view for explaining a substrate processing apparatus in accordance with an exemplary embodiment;

FIG. 2 is a view for explaining a heater block and a heating lamp in accordance with an exemplary embodiment;

FIGS. 3 to 5 are views for explaining a heater block and a heating lamp in accordance with modified examples; and

FIGS. 6 to 7 are views for explaining the heater block and the heating lamp in accordance with an exemplary embodiment and modified examples.

### DETAILED DESCRIPTION OF EMBODIMENTS

Hereinafter, embodiments of the present invention will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

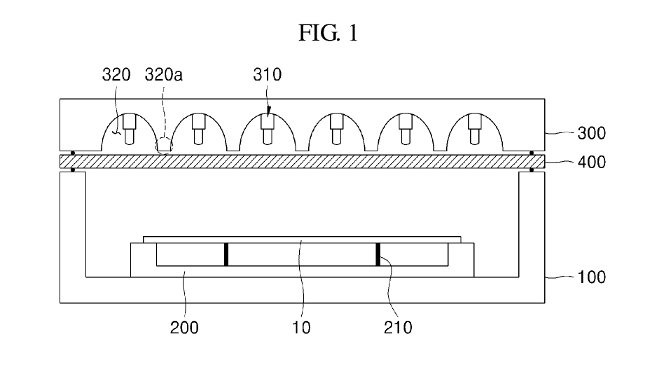

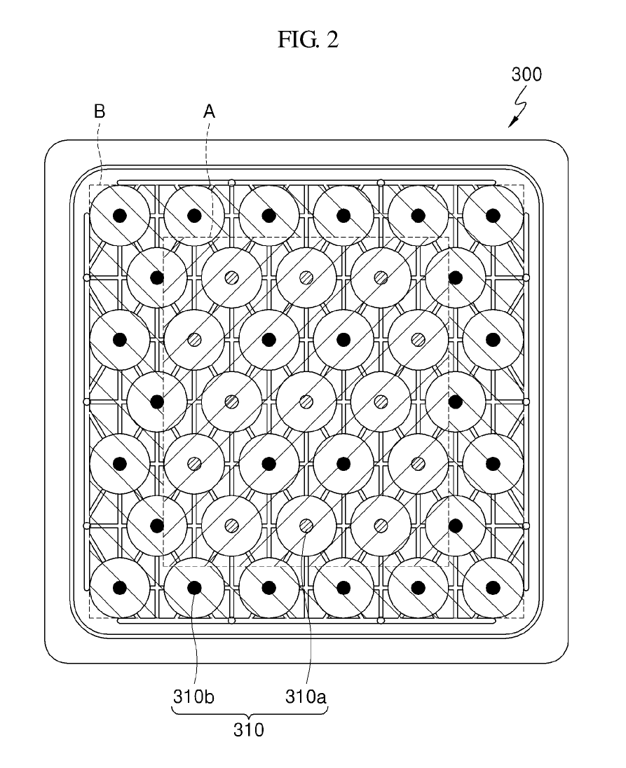

FIG. 1 is a cutaway side view illustrating one side of a substrate processing apparatus so as to explain a substrate processing apparatus in accordance with an exemplary embodiment, and FIG. 2 is a plan view illustrating a lamp mounting surface of a heater block to explain a structure for arranging first and second lamps of the heater block in accordance with an exemplary embodiment.

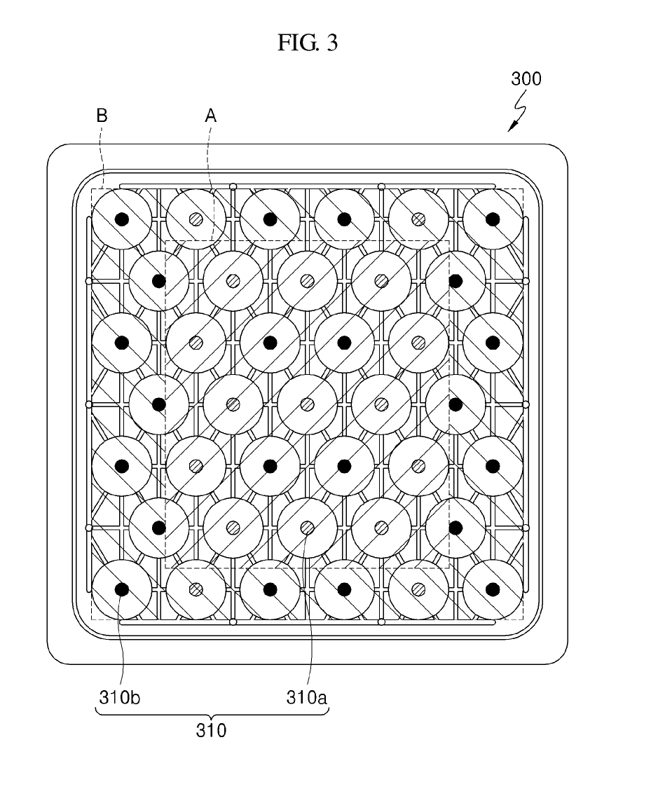

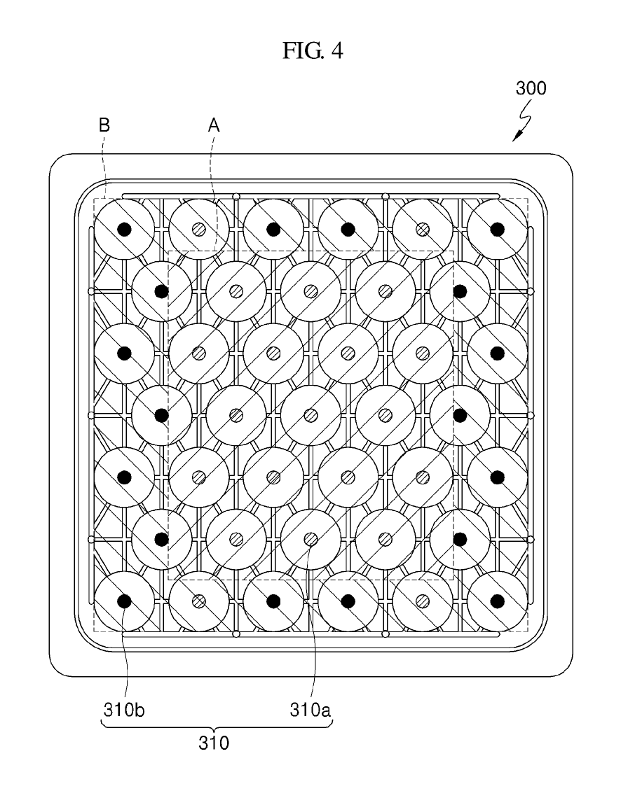

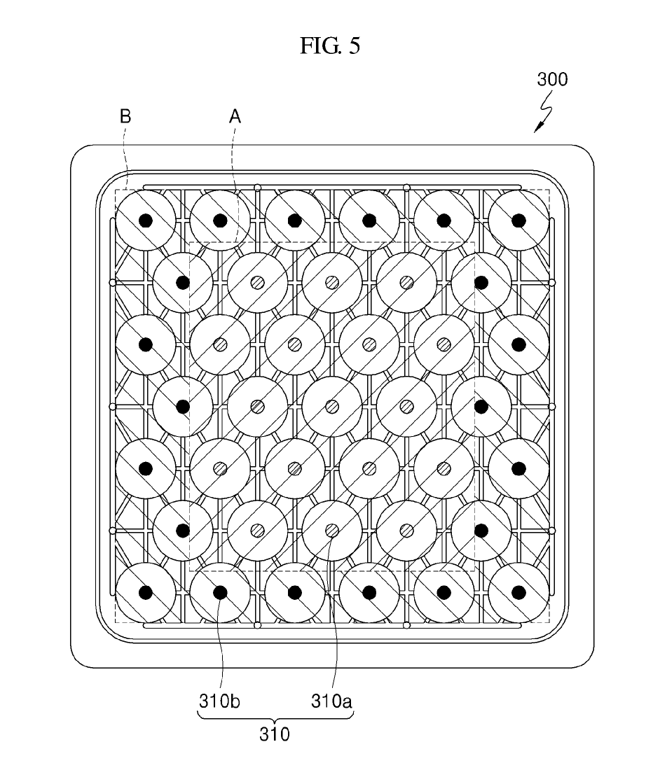

Also, FIG. 3 is a plan view illustrating the lamp mounting surface of the heater block to explain a structure for arranging first and second lamps of the heater block in accordance with a modified example, FIG. 4 is a plan view illustrating the lamp mounting surface of the heater block to explain a structure for arranging first and second lamps of the heater block in accordance with another modified example, and FIG. 5 is a plan view illustrating the lamp mounting surface of the heater block to explain a structure for arranging first and second lamps of the heater block in accordance with yet another modified example.

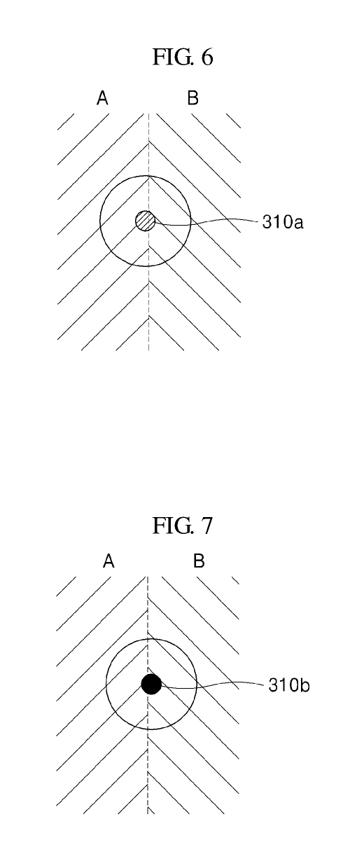

Also, FIGS. 6 to 7 are plan views for explaining a method for selectively mounting the heating lamp mounted on one surface of the heater block, e.g., the lamp mounting surface on a boundary between a central area and a surrounding area of the above-described one surface in accordance with an embodiment and modified examples.

Referring to FIGS. 1 and 2, a substrate processing apparatus in accordance with an exemplary embodiment includes a chamber 100 having an inner space in which the substrate is processed, a substrate support unit disposed on an inner lower side of the chamber 100 to support the substrate 10, a heater block 300 disposed to face the substrate support unit, and a transmission member disposed between the chamber 100 and the heater block 300 to separate the heater block 300 from the chamber 100.

The substrate 10 may include a large sized glass substrate that is applied as a base material in a process for manufacturing various kinds of display devices including AMOLED, LCD, OLED, and LED or various kinds of electronic devices including a solar cell and a semiconductor chip. For example, the substrate 10 may include a glass substrate applied in a process for dehydronating a gate insulation film or a process for caring a polyimide (PI) film of unit processes for manufacturing a TFT substrate.

Here, the above-described substrate 10 may have a rectangular plate shape, and a film of an oxide to be heat-treated, e.g., a gate insulation film, may be provided to an upper surface thereof. The film of the oxide disposed on the substrate 10 may be irradiated by ultraviolet (UV) rays or infrared (IR) rays, which are generated from a heater block 300 that will be described later, and dehydrogenated.

Of course, the substrate 10 in accordance with an exemplary embodiment is not limited thereto. For example, the substrate 10 may include various kinds of substrates having the upper surface on which various layers to be processed containing hydrogen are disposed.

The chamber 100 may have, e.g., a hollow block shape of which an inside is upwardly opened. A gate (not shown) through which the substrate 10 passes may be provided on one of side surfaces of the chamber 100, and a transfer robot (not shown) for loading the substrate 10 into the chamber 100 and unloading the substrate 10 out of the chamber 100 may be provided outside the gate.

Meanwhile, although not shown in the drawings, a gas supply unit and a gas exhaust unit for providing an ambient gas into the chamber 100 and exhausting the provided ambient gas may be further provided to one side of the chamber 100 to control inner ambience of the chamber 100

The inside of the chamber 100 may be sealed to form a substrate processing space for processing a substrate, and a substrate support unit may be disposed on an inner lower side of the chamber 100 to stably support the substrate 10 while a predetermined process for processing the substrate in the chamber 100. Here, the substrate support unit may have various structures corresponding to a size and shape of the substrate 10. For example, the substrate support unit may include an edge ring 200 having an upper surface of a ring shape to support a lower portion of an edge of the substrate while the substrate 10 is heat-treated.

Also, the substrate support unit may include a plurality of lift pins 210, and the lift pins 210 may support the substrate 10 loaded into the chamber 10 and lift and descend the substrate 10 while the substrate 10 is loaded and unloaded.

In describing an exemplary embodiment of the present disclosure, although the above-described chamber 100 and the substrate support unit may have various constitutions and manners, an exemplary embodiment of the present disclosure is not limited thereto.

The heater block 300 serves to provide radiant energy in a form of infrared rays and ultraviolet rays to the substrate 10 that is loaded into the chamber 100. That is, the heater block 300 may irradiate, e.g., infrared ray and ultraviolet ray to the substrate 10 seated on the substrate support unit. The heater block 300 is mounted on an upper portion of the chamber 100 to firmly cover the opened upper portion of the chamber 100 to face the substrate support unit, and a heating lamp 310 having, e.g., a bulb shape may be provided on one surface of the heater block 300 facing the substrate support unit to heat-treat the substrate 10, e.g., a lamp mounting surface.

A transmission member 400 may be disposed between the chamber 100 and the heater block 300. For example, the transmission member 400 may include a quartz window. The transmission member 400 serves to enable light generated from the heating lamp 310, e.g., the infrared ray and the ultraviolet ray to transmit into the chamber 100.

A sealing unit is disposed on each of coupling surfaces between the transmission member 400 and the heater block 300 and between the transmission member 400 and the chamber 100 to thus firmly seal the inside of the chamber 100 and maintain vacuum of the heater block 300.

Hereinafter, the heater block 300 in accordance with an exemplary embodiment and modified examples will be described in more detail with reference to FIGS. 1 to 7.

The heater block 300 includes a plurality of heating lamps 310 mounted on one surface thereof facing the substrate 10 so as to irradiate light to an object to be processed, e.g., the substrate 10, and process the substrate 10. The heater block 300 is mounted to cover the opened upper portion of the chamber 100 to seal the inside of the chamber 100 and also serves to irradiate the light to the substrate 10 that is loaded into the chamber 100 by using the plurality of heating lamps 310 provided to the one surface, e.g., the lamp mounting surface.

A plurality of lamp mounting grooves 320 may be defined in the above-described one surface of the heater block 300, and the lamp mounting groove 320 may have a hemispherical shape of which a lower portion is opened. The heating lamp 310 is installed in the lamp mounting groove 320. Here, the heating lamp 310 may be mounted in a direction crossing the one surface of the heater block 300, e.g., a vertical direction. Although not specifically shown in the drawings, the heating lamp 310 may include a socket disposed on an upper end of a lamp body having, e.g., a hollow cylindrical shape and coupled to the lamp mounting groove to receive an external power. Here, the lamp body may be made of glass or quartz, and the inside of the lamp body may be filled with, e.g., a halogen gas.

As described above, as the heating lamp 310 is mounted in the lamp mounting groove 320, a structural effect in which each of the heating lamps 310 is isolated by, e.g., a partition 320a may be achieved, and thus light interference between the heating lamps 310 that are disposed adjacent to each other may be prevented. This will be described in more detail.

In accordance with an exemplary embodiment, the lamp mounting groove 320 having a space for accommodating the heating lamp 310, of which a lower portion is opened, may be provided on the one surface of the heater block 300, e.g., a plurality of positions on the lamp mounting surface. The heating lamps 310 may be respectively mounted in the lamp mounting grooves 320 and respectively disposed in the lamp mounting grooves 320.

That is, the heating lamps 310 may be horizontally spaced apart from each other and respectively disposed in the spaces that are separated from each other to be spaced apart and isolated from each other. Thus, light emission areas of the plurality of heating lamps 310 may not overlap each other. In other words, the light irradiated from one of the heating lamps 310 may not be directly irradiated to the rest heating lamps except for the above-described one of the heating lamps.

Especially, as described below, when the heating lamp 310 includes an ultraviolet rays lamp 310a and an infrared rays lamp 310b, the light interference between the ultraviolet rays and the infrared rays may be prevented, and thus irradiation of the ultraviolet rays and the infrared rays may be more efficiently performed to increase efficiency for processing the substrate and lifetimes of the ultraviolet rays lamp 310a and an infrared rays lamp 310b.

In accordance with an exemplary embodiment, the heating lamp 310 may include the ultraviolet rays lamp 310a and the infrared rays lamp 310b. The ultraviolet rays lamp 310a irradiates ultraviolet rays to the substrate 10 to chemically debond hydrogen-silicon (Si—H) bond of a gate insulation film disposed on the substrate 10. Also, the infrared rays lamp 310b, e.g., a halogen infrared rays lamp, irradiates infrared rays toward the substrate 10 to enable hydrogen to be escaped from the gate insulation film, i.e., dehydrogenation treatment, in a method in which temperatures of the substrate 10 and in the chamber 100 increases to heat and evaporate the debonded hydrogen.

When the above-described heating lamp 310 includes only the ultraviolet rays lamp 310a, it is difficult to heat the substrate 10 upto a temperature at which the substrate 10 is dehydrogenated. On the other hand, when the heating lamp 310 includes only the infrared rays lamp 310b, since the hydrogen-silicon bond is debonded by only infrared rays radiant energy, high temperature environment of approximately 450└ or more is demanded in the chamber, and thus a time for heating the substrate increases to thus increase a total processing time.

Accordingly, in accordance with an exemplary embodiment, the heating lamp 310 may include the ultraviolet rays lamp 310a together with the infrared rays lamp 310b, and the plurality of first lamps 310a irradiating ultraviolet (UV) rays to the substrate and the plurality of second lamps 310b irradiating infrared (IR) rays to the substrate may be horizontally spaced apart from each other on the one surface of the heater block 300 facing the substrate 10.

As described above, since each of the plurality of first and second lamps 310a and 320b is horizontally spaced, the heater block 300 may two-dimensionally control the temperature of the substrate 10 while the substrate 10 is processed with reference to the upper surface of the substrate 10, to which the light is irradiated. Thus, since thermal compensation for an edge area of the substrate 10 may be two dimensionally compensated, thermal uniformity may be relatively easily secured when compared to the related art.

Furthermore, in accordance with an exemplary embodiment, as illustrated in FIG. 2, the plurality of heating lamps 310 may be arranged to constitute a row and column on the one surface of the heater block 300, and the heating lamps 310 constituting the adjacent row may be alternately arranged with respect to the heating lamps constituting any one of the rows. Similarly, the heating lamps constituting the adjacent column may be alternately arranged to each other with respect to the heating lamps constituting any one of the columns.

Here, with reference to FIG. 2, when a transverse direction is one direction, and a longitudinal direction is the other direction, the above-described “heating lamps constituting any one of the rows” may represent the heating lamps arranged in the one direction on a predetermined position on the one surface of the heater block 300 on which the heating lamps 310 are mounted. Likewise, “the heating lamps constituting any one of the columns” may represent the heating lamps arranged in the other direction on the above-described predetermined position of the one surface of the heater block 300.

In summary, each of the heating lamps 310 that are adjacent to each other may be arranged in a triangular or hexagonal shape on the one surface of the heater block 300. Thus, the heating lamps 310 may be densely arranged on the one surface of the heater block 300 with the minimum number of heating lamp 310 and also uniformly spaced apart from each other on the one surface of the heater block 300.

Meanwhile, in accordance with an embodiment and modified examples, the one surface of the heater block 300 facing the substrate 10 may include a plurality of areas, and a relative ratio of the number of first lamp 310a to the number of second lamp 310b may be different for the plurality of areas on the above-described one surface.

For example, the heater block 300 may have one surface facing the substrate 10, which is divided into a central area A having a size and shape corresponding to those of the substrate 10 and a surrounding area B surrounding the central area A. The first lamp 310a and the second lamp 310b may be mounted to the one surface of the heater block 300 so that the relative ratio of the number of first lamp 310a to the number of second lamp 310b is different.

Here, the first lamp 310a may be mounted on at least the central area A of the central area A and the surrounding area B, and the second lamp 310b may be mounted on at least the surrounding area B of the central area A and the surrounding area B. That is, the first lamp 310a and the second lamp 310b may be mounted together on each of the central area A and the surrounding area B (refer to FIG. 3), the first lamp 310a and the second lamp 310b may be mounted together on the central area A and only the second lamp 310b may be mounted on the surrounding area B (refer to FIG. 2), only the first lamp 310a may be mounted on the central area A and the first lamp 310a and the second lamp 310b may be mounted together on the surrounding area B (refer to FIG. 4), or only the first lamp 310a may be mounted on the central area A and only the second lamp 310b may be mounted on the surrounding area B (refer to FIG. 5)

Especially, in accordance with an embodiment and modified examples, when the heating lamp 310 is mounted on the central area A, the ratio of the number of first lamp 310a to the number of second lamp 310b may be selected so that the number of first lamp 310a mounted on the central area A exceeds approximately 50% of the total number of heating lamp 310 mounted on the central area A. Also, when the heating lamp 310 is mounted on the surrounding area B, the ratio of the number of first lamp 310a to the number of second lamp 310b may be selected so that the number of second lamp 310b mounted on the surrounding area B exceeds 50% over the total number of the heating lamp 310 mounted on the surrounding area B.

Here, when the number of first lamp 310a mounted on the central area A is equal to or less than approximately 50% of the total number of heating lamp 310 mounted on the central area A, it may be difficult to irradiate a desirable amount of ultraviolet rays to the substrate 10 disposed on a lower portion of the heater block 300, and thus a predetermined film disposed on the substrate 10 may not chemically separate hydrogen. Also, when the number of second lamp 310b mounted on the surrounding area B is equal to or less than 50% of the total number of heating lamp 310 mounted on the surrounding area B, it may be difficult to sufficiently provide infrared rays radiant energy for thermal compensation of the edge area of the substrate to the substrate. Accordingly, in accordance with an exemplary embodiment, the first lamp 310a and the second lamp 310b are mounted for each of the areas to satisfy the above-described relative ratio of the number of first lamp 310a to the number of the second lamp 310b.

Thus, in accordance with an exemplary embodiment, the relatively many number of first lamps 310a may be mounted on the central area A of the one surface of the heater block 300 to evenly irradiate the ultraviolet rays onto the substrate 10 and thus debond the chemical bond of the hydrogen in a hydrogen compound contained in a predetermined film disposed on the substrate 10. Also, the relatively many number of the second lamps 310a may be mounted on the surrounding area B to irradiate the relatively large amount of infrared rays onto the edge area of the substrate 10 and thus compensate the temperature of the edge area of the substrate 10.

Meanwhile, in accordance with an exemplary embodiment and modified examples, when the first lamp 310a and the second lamp 310b are mounted on the boundary between the central area A and the surrounding area B, any one of the first lamp 310a and the second lamp 310b may be selectively mounted on the boundary between the central area A and the surrounding area B with reference to a method that will be described below. The method will be described below. The first lamp 310a may be selectively mounted as the heating lamp 310 that is mounted on the boundary between the central area A and the surrounding area B when a surface area of the heating lamp 310 on the central area A is equal to or greater than approximately 50% of an entire surface area of the heating lamp 310 with reference to the boundary between the central area A and the surrounding area B. This is illustrated in FIG. 6.

Also, the second lamp 310b may be mounted as the heating lamp 310 that is mounted on the boundary between the central area A and the surrounding area B when the surface area of the heating lamp 310 on the surrounding area B exceeds approximately 50% of the entire surface area of the heating lamp 310 with reference to the boundary between the central area A and the surrounding area B. This is illustrated in FIG. 7.

That is, when the heating lamp 310 is mounted biased to the central area A, the first lamp 310a may be selectively mounted, and, when the heating lamp 310 is mounted biased to the surrounding area B, the second lamp 310b may be selectively mounted.

In selecting one of the first lamp 310a and the second lamp 310b as the heating lamp 310 that is mounted on the boundary between the central area A and the surrounding area B, the above-described selection method is corresponded to the selection of the relative ratio of the number of first lamp 310a to the number of second lamp 310b in the surround area B for the thermal compensation of the edge area of the substrate 10. Thus, the temperature at the edge area of the substrate 10 may be efficiently compensated to increase temperature uniformity of the substrate 10.

Meanwhile, besides the above-described compensation of the temperature of the edge area of the substrate 10, due to various reasons in the process, when each of the infrared rays and the ultraviolet rays is differently irradiated to various areas of the substrate 10, the first lamp 310a and the second lamp 310b may be mounted so that the one surface of the heater block 300 is divided in various methods that is different from the above-described method and the relative ratio of the number of first lamp 310a to the number of second lamp 310b is different. That is, the method for arranging the heating lamp 310 mounted on the one surface of the heater block 300 may variously change by corresponding to a case in which kind, intensity, and the like of the light irradiated for each position of the substrate in a process for processing the substrate is controlled.

Also, although the heater block 300 applied to the substrate processing apparatus is described as an example, the heater block 300 in accordance with an exemplary embodiment may be also applied to various kinds of processing apparatuses irradiating the infrared rays together with the ultraviolet rays to various objects to be processed provided in a predetermined space in addition to the substrate processing apparatus.

As described above, in accordance with an exemplary embodiment, the heater block and the substrate processing apparatus including the same show technical characteristics that are capable of thermally compensating the edge area of the substrate to further increase the temperature uniformity of the substrate.

For example, in the related art, while the infrared rays and the ultraviolet rays are irradiated to the substrate 10 to process the substrate 10, the temperature of the edge area of the substrate is less than that of the central area of the substrate except for the edge area of the substrate to decrease the temperature uniformity of the substrate 10. Although, in the related art, the hydrogenation treatment is unevenly performed on the entire area of the substrate to decrease a quality of the substrate, as described above, in accordance with an exemplary embodiment, the first lamp 310a and the second lamp 310b are provided as described above to compensate the temperature of the edge area of the substrate, thereby securing the temperature uniformity of the entire substrate and increasing the quality of the substrate to be processed.

In accordance with an exemplary embodiment, the efficiency for processing the substrate to be processed may increase. For example, when the first lamp irradiating the ultraviolet rays and the second lamp irradiating the infrared rays are mounted together on the central area of the one surface of the heater block facing the substrate, the first lamp is mounted greater in number than the second lamp, or only the first lamp is mounted to uniformly control the chemical separation of hydrogen in the entire area of the substrate surface to be processed, thereby increasing the efficiency for processing the substrate.

Also, in accordance with an exemplary embodiment, the temperature uniformity of the substrate to be processed may increase. For example, when the first lamp and the second lamp are mounted together on the surrounding area surrounding the central area of the one surface of the heater block, the second lamp may be mounted greater in number than the first lamp, or only the second lamp is mounted to thermally compensate the edge area of the substrate, thereby increasing the temperature uniformity of the substrate. Also, as the temperature uniformity of the substrate increases, the dehydrogenation treatment may be uniformly controlled over the entire area of the substrate surface to be processed to increase the efficiency for processing the substrate.

Also, in accordance with an exemplary embodiment, as each of the first lamp and the second lamp passes through the one surface of the heater block and be mounted in each of the plurality of lamp grooves that are horizontally spaced apart from each other to prevent the light interference between the first lamp and the second lamp, which are disposed adjacent to each other. Accordingly, since the infrared rays irradiated from the second lamp is prevented from being reached to the first lamp, the temperature rise and thermal damage of the first lamp caused by the infrared rays radiant energy may be suppressed or prevented to increase the lifetime of the first lamp. Also, the ultraviolet rays irradiated from the first lamp may be prevented from being reached to the second lamp to suppress or prevent the ultraviolet radiant energy from being reduced by the infrared rays irradiated from the second lamp.

The embodiments and comparative examples of the present invention give further detailed description to help understanding of the prevent invention, but do not limit the scope of the present invention. Embodiments of the present invention may be modified in other forms within the technical idea and scope of the present invention. Also, the technical ideas according to the embodiment and comparative examples may be realized by coupling and applying to each other in various methods. Various embodiments may be provided to allow those skilled in the art to understand the scope of the preset invention, but the present invention is not limited thereto.

What is claimed is:

1. A heater block comprising a plurality of heating lamps mounted on one surface thereof facing an object to be processed,
wherein the heating lamp comprises a first lamp configured to irradiate ultraviolet (UV) rays to the object to be processed and a second lamp configured to irradiate infrared (IR) rays to the object to be processed, and
a relative ratio of the number of first lamp to the number of second lamp is different for each of a plurality of areas on the one surface.

2. The heater block of claim 1, wherein the plurality of areas on the one surface comprise a central area having a size and shape corresponding to those of the object to be processed and a surrounding area surrounding the central area.

3. The heater block of claim 2, wherein the first lamp and the second lamp are mounted together on each of the central area and the surrounding area.

4. The heater block of claim 2, wherein the first lamp and the second lamp are mounted together on the central area, and
the second lamp is mounted on the surrounding area.

5. The heater block of claim 2, wherein the first lamp is mounted on the central area, and
the first lamp and the second lamp are mounted together on the surrounding area.

6. The heater block of claim 2, wherein the first lamp is mounted on the central area, and
the second lamp is mounted on the surrounding area.

7. The heater block of claim 2, wherein the number of first lamp mounted on the central area exceeds approximately 50% of the total number of heating lamp mounted on the central area.

8. The heater block of claim 2, wherein the number of second lamp mounted on the surrounding area exceeds approximately 50% of the total number of heating lamp mounted on the surrounding area.

9. The heater block of claim 2, wherein the first lamp and the second lamp are selectively mounted on a boundary between the central area and the surrounding area, and
the first lamp is mounted when a surface area of the heating lamp on the central area is equal to or greater than approximately 50% of an entire surface area of the heating lamp with reference to the boundary between the central area and the surrounding area, and the second lamp is mounted when the surface area of the heating lamp on the surrounding area exceeds approximately 50% of the entire surface area of the heating lamp with reference to the boundary between the central area and the surrounding area.

10. A substrate processing apparatus configured to process a substrate, the substrate processing apparatus comprising:
a chamber having an inner space in which the substrate is processed;
a substrate support unit disposed in the chamber to support the substrate;
a heater block disposed to face the substrate support unit; and
a transmission member disposed between the chamber and the heater block,
wherein a first lamp configured to irradiate ultraviolet (UV) rays to the substrate and a second lamp configured to irradiate infrared (IR) rays to the substrate are provided in plurality and spaced apart from each other on one surface of the heater block facing the substrate.

11. The substrate processing apparatus of claim 10, wherein the one surface of the heater block comprises a central area facing an object to be processed and a surrounding area surrounding the central area, and
the first lamp is mounted on at least the central area of the central area and the surrounding area of the one surface.

12. The substrate processing apparatus of claim 10, wherein the one surface of the heater block comprises a central area facing the object to be processed and a surrounding area surrounding the central area, and
the second lamp is mounted on at least the surrounding area of the central area and the surrounding area of the one surface.

13. The substrate processing apparatus of claim 11, wherein a ratio of the number of first lamp to the number of second lamp is different for each of the central area and the surrounding area.

14. The substrate processing apparatus of claim 12, wherein a ratio of the number of first lamp to the number of second lamp is different for each of the central area and the surrounding area.

15. The substrate processing apparatus of claim 13, wherein the number of first lamp mounted on the central area exceeds approximately 50% of the total number of heating lamp mounted on the central area, and
the number of second lamp mounted on the surrounding area exceeds approximately 50% of the total number of heating lamp mounted on the surrounding area.

16. The substrate processing apparatus of claim 14, wherein the number of first lamp mounted on the central area exceeds approximately 50% of the total number of heating lamp mounted on the central area, and
the number of second lamp mounted on the surrounding area exceeds approximately 50% of the total number of heating lamp mounted on the surrounding area.
